(19) United States
(12) Patent Application Publication
(10) Pub. No.: US 2010/0327899 A1
(43) Pub. Date: Dec. 30, 2010

(54) DESIGN SUPPORT APPARATUS AND DESIGN SUPPORT METHOD

(75) Inventor: Yusuke IMAIZUMI, Ome-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/827,724

(22) Filed: Jun. 30, 2010

(30) Foreign Application Priority Data
Jun. 30, 2009 (JP) 2009-156006

(51) Int. Cl. G01R 31/00

(52) U.S. Cl. 324/756.05

(57) ABSTRACT

According to one embodiment, a design support apparatus includes a first detector configured to detect a cable connected to the printed circuit board, a second detector configured to detect a conducting component from components of a housing, a third detector configured to detect an electromagnetic wave radiating component from electronic components mounted on the printed circuit board, a fourth detector configured to detect a path which propagates the electromagnetic waves, a first setting module configured to set, as sources, the electromagnetic wave radiating component and the path, a second setting module configured to set, for the sources, intensity attributes corresponding to an operation clock frequency of the electromagnetic wave radiating component, a calculator configured to calculate spaces of the sources, the spaces includes volumes corresponding to the intensity attributes, and a determining module configured to determine whether at least one of the cable passes at least one of the spaces.

### CROSS-REFERENCE TO RELATED APPLICATIONS

This application is based upon and claims the benefit of priority from Japanese Patent Application No. 2009-156006, filed Jun. 30, 2009; the entire contents of which are incorporated herein by reference.

### FIELD

Embodiments described herein relate generally to a design support apparatus and a design support method for examining a path to extend cables to be disposed in a housing in consideration of EMI.

### BACKGROUND

Electromagnetic interference (unnecessary electromagnetic radiation, hereinafter referred to as EMI) has been a problem as a result of enhanced functions of electronic devices and increasing speed of signal transmission. The intensity of electromagnetic waves radiated from an electronic device not only depends on the operation of ICs as noise sources but is also decided by a path that efficiently transmits the noise and by the shape of an antenna that efficiently radiates the transmitted noise into space. Therefore, when the design of an electronic device is considered from the perspective of EMI countermeasures, how to suppress these three factors (noise source, noise propagation path, antenna element) matters.

One of the points to notice in the EMI design of an electronic device is the path to extend cables. The cables serve as noise propagation paths for catching and transmitting noise from a noise source on a substrate, and for their elongate shape, also serve as antenna elements for extremely efficiently radiating the noise. Thus, the path to extend the cables in a housing has to be carefully selected from an upstream stage of designing and then decided.

According to a technique disclosed in Jpn. Pat. Appln. KOKAI Publication No. 2002-149720, mechanical CAD data and electric CAD data are connected by an electromagnetic environment adaptation/examination support apparatus, and an EMI calculation is performed to indicate an EMI level. When the EMI level is greater than or equal to a prescribed level, a warning is indicated, and how to lay a harness is changed.

In order to calculate the EMI level, an electromagnetic field equation has to be solved. However, processing for solving the electromagnetic field equation is complicated and time-consuming.

### BRIEF DESCRIPTION OF THE DRAWINGS

A general architecture that implements the various feature of the embodiments will now be described with reference to the drawings. The drawings and the associated descriptions are provided to illustrate the embodiments and not to limit the scope of the invention.

FIG. 1 is an exemplary block diagram showing the configurations of a design support apparatus and a storage device according to one embodiment of the present invention.

FIG. 2 is an exemplary diagram for illustrating a noise radiating component, a noise propagation path and an antenna element within an electronic device.

FIG. 3 is an exemplary halftone image showing an example of setting noise intensity attributes for noise sources corresponding to the noise radiating components.

FIG. 4 is an exemplary halftone image showing an example of setting noise intensity attributes for noise sources corresponding to wirings.

FIG. 5 is an exemplary halftone image showing an example of superposing information indicating a power source/GND resonance analysis on a figure indicating a printed circuit board.

FIG. 6 is an exemplary halftone image in which noise generating spaces are visualized around noise sources on the basis of the set noise intensity attributes.

FIG. 7 is an exemplary diagram showing an example of a cable which passes the noise generating space and is regarded as faulty.

FIG. 8 is an exemplary flowchart showing a procedure for processing to examine the placement of a cable/harness.

### DETAILED DESCRIPTION

Various embodiments will be described hereinafter with reference to the accompanying drawings.

In general, according to one embodiment, design support apparatus includes a cable/harness detector, a conducting component detector, a radiating component detector, an electromagnetic wave radiation source setting module, an intensity setting module, a calculator, and a determining module. The cable/harness detector configured to detect a cable and harness from mechanical design data for a housing in which a printed circuit board is disposed, the cable and harness being connected to the printed circuit board. The conducting component detector configured to detect, from components of the housing, a conducting component which is made of a conductor based on the mechanical design data. The radiating component detector configured to detect, from electronic components mounted on the printed circuit board, an electromagnetic wave radiating component which radiates electromagnetic waves based on board design data for the printed circuit board. The propagation path detector configured to detect a propagation path which propagates the electromagnetic waves radiated from the electromagnetic wave radiating component based on the board design data and the conducting component detected by the conducting component detector. The electromagnetic wave radiation source setting module configured to set, as different electromagnetic wave radiation sources, the electromagnetic wave radiating component detected by the radiating component detector and the propagation path detected by the propagation path detector. The intensity setting module configured to set, for the electromagnetic wave radiation sources set by the electromagnetic wave radiation source setting module, intensity attributes corresponding to an operation clock frequency of the electromagnetic wave radiating component. The calculator configured to calculate electromagnetic wave generating spaces of the electromagnetic wave radiation sources, the electromagnetic wave generating spaces comprising volumes corresponding to the intensity attributes respectively. The determining module configured to determine whether at least one of the cable and harness passes at least one of the electromagnetic wave generating spaces.

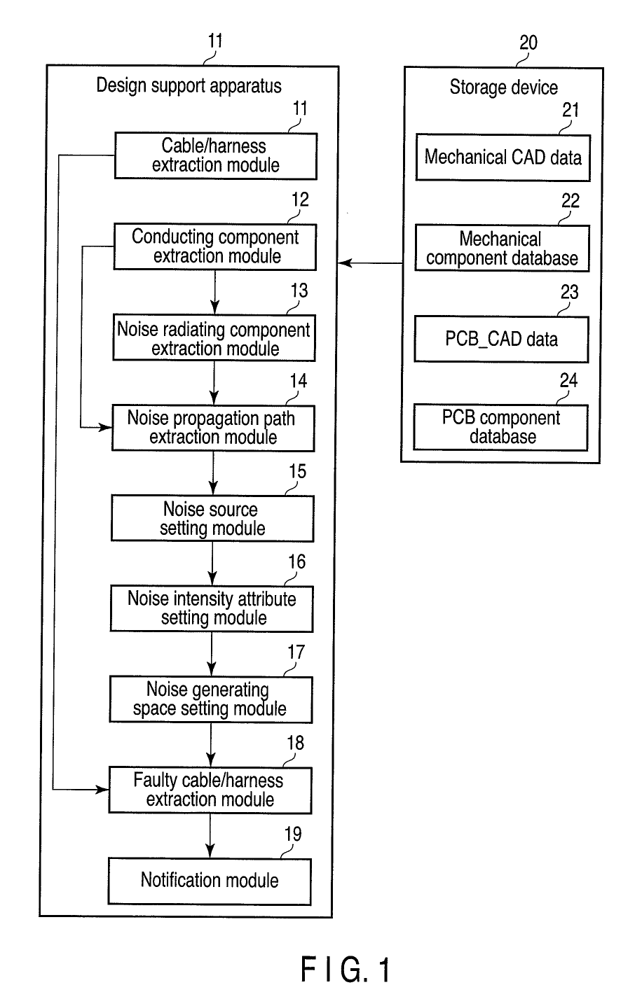

FIG. 1 is a block diagram showing the configurations of a design support apparatus 10 and a storage device 20 according to one embodiment of the present invention.

As shown in FIG. 1, the design support apparatus 10 comprises a cable/harness extraction module 11, a conducting component extraction module 12, a noise radiating component extraction module 13, a noise propagation path extraction module 14, a noise source setting module 15, a noise intensity attribute setting module 16, a noise generating space setting module 17, a faulty cable/harness extraction module 18 and a notification module 19. The storage device 20 stores mechanical CAD data 21, a mechanical component database 22, PCB_CAD data 23 and a PCB component database 24.

In addition, processing to be performed by the design support apparatus according to the present embodiment to examine a path to extend a cable or harness to be disposed in a housing is enabled by a computer program to be executed by a computer.

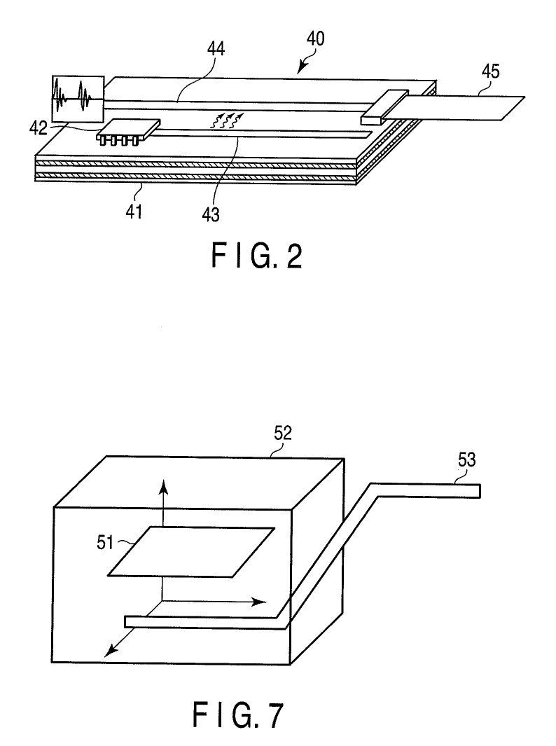

Before describing the configuration of the apparatus 10 in detail, an overview of this apparatus is described. FIG. 2 specifically shows a noise radiating component (electromagnetic wave radiating component), a noise propagation path (electromagnetic wave propagation path) and an antenna element within an electronic device. The electronic device has a printed circuit board 40. The printed circuit board 40 has a printed wiring board 41, an IC 42 mounted on the printed wiring board 41, and wirings 43, 44 printed on the printed wiring board 41. A cable 45 is connected to the printed circuit board 40.

Firstly, a noise component in the electronic device is the IC 42 mounted on the printed wiring board 41. The intensity of noise (electromagnetic waves) radiated by the IC 42 is decided by the operation speed and drive current amount of the IC 42 and by the layout around the IC.

Secondly, the noise propagation path for propagating the noise generated by the IC 42 includes the wirings 43, 44 provided on the printed circuit board, the cable 45 and others connected to the printed circuit board 40, and metal mechanical components constituting the housing. The metal well transmits not only signals but also noise, so that all of the metal components can be noise propagation paths. In addition, the wiring 44 is not connected to the IC 42. However, the noise propagated by the wiring 43 which is connected to the IC 42 adjacent to the wiring 44 is transmitted to the wiring 44 via the printed wiring board 41.

Thirdly, all of the metal components can be antenna elements as in the case of the noise propagation path. However, the frequency that easily radiates noise into space varies depending on the shape and size of an antenna. The cable (harness) 45 on which attention is now particularly focused becomes a problem not only as a noise propagation path but also as an antenna element in many cases.

In the apparatus 10, the noise radiating component and the noise propagation path are extracted as noise radiation sources. Then, the apparatus 10 sets the intensity of noise (intensity of electromagnetic waves) radiated by the noise radiation sources. At the same time, the amount of noise radiated by the noise radiating component which is the IC is decided based on an operation clock frequency. When the noise intensity is set for the noise source which is the noise propagation path, a noise intensity is set which is lower than the noise intensity set for a noise supply source serving to supply noise to the noise source. Then, the apparatus 10 sets, for the printed circuit board, a noise generating space having a size corresponding to the noise intensity. The noise generating space is a space around the noise radiation source. Further, the apparatus 10 judges whether there is a cable or harness to be an antenna element in the noise generating space. When judging that there is such a cable or harness, the apparatus 10 notifies an operator that there is a cable or harness in the noise generating space, and the apparatus 10 prompts the operator to change the arrangement location of the cable or harness.

The intensity of the noise radiated by the IC is set based on the operation clock frequency, and there is thus no need for processing to solve an electromagnetic field equation. This makes it possible to reduce the time required for the examination of a cable (harness) extending path that takes EMI into account.

Now, the configuration of the design support apparatus 10 shown in FIG. 1 and data stored in the storage device 20 are described.

The storage device 20 stores the mechanical CAD data 21 which includes the shapes and installation coordinates of the components constituting the housing and the shape and installation coordinates of the cable and harness provided in the housing. The storage device 20 also stores the mechanical component database 22 in which the attributes of the materials of the components constituting the housing and the cable and harness provided in the housing are registered.

The storage device 20 further stores the PCB_CAD data 23 which includes the shape of the printed circuit board provided in the housing, the placement coordinates of the wirings provided on the printed circuit board, and the shapes and arrangement coordinates of the components mounted on the printed circuit board. Moreover, the storage device 20 stores the PCB component database 24 in which information such as the operation clock frequencies of the components mounted on the printed circuit board is registered.

The cable/harness extraction module 11 extracts the cable and harness to be the antenna element from the mechanical component database 22. The cable/harness extraction module 11 first acquires the mechanical CAD data 21, and then acquires component material information included in the mechanical CAD data 21 from the mechanical component database 22, thereby extracting the cable or harness.

Furthermore, the conducting component extraction module 12 acquires, from the mechanical component database 22, the component material information included in the mechanical CAD data 21, and thereby extracts components made of conductors from the components constituting the housing.

The noise radiating component extraction module 13 acquires, from the PCB component database 24, the attributes of the components included in the PCB_CAD data 23, and thereby extracts noise radiating components that radiate nose (electromagnetic waves). The noise radiating components are electronic components such as an IC driven at high frequency.

Then, based on the conducting components extracted by the conducting component extraction module 12 and the PCB_CAD data 23 and the PCB component database 24, the noise propagation path extraction module 14 extracts noise propagation paths such as the wirings and the metal components serving to propagate the noise which is radiated from the noise radiating components extracted by the noise radiating component extraction module 13.

The noise propagation path extraction module 14 acquires the attributes of the components included in the PCB_CAD data 23 from the PCB component database 24, and extracts components corresponding to a wiring attribute. From the extracted wirings, the noise propagation path extraction module 14 extracts, as a noise propagation path, a wiring which propagates the noise radiated from the noise radiating component.

The noise source setting module 15 sets, as different noise sources, the noise radiating component extracted by the noise radiating component extraction module 13 and the noise propagation path extracted by the noise propagation path extraction module 14.

The noise source setting module 15 sets the noise sources by any one or a combination of the following methods:

The individual noise radiating components mounted on the printed circuit board are set as noise sources.

The individual noise radiating components (ICs) mounted on the printed circuit board are further set as noise sources pin by pin.

The space including the noise radiating components mounted on the printed circuit board is set as a noise source. For example, the space including control ICs, coils and diodes that constitute a switching power supply circuit is set as a noise source.

The individual wirings (noise propagation paths) provided on the printed circuit board are set as noise sources.

A portion of each of the wirings on the printed circuit board is set as a noise source. For example, instead of setting, as a noise source, one whole wiring which has been extracted as a propagation path, a portion of the wiring is set as a noise source. Moreover, for example, the wiring (propagation path) provided in an outermost wiring layer among a plurality of wiring layers provided on the printed circuit board is set as a noise source.

The characteristic impedance of the wiring is analyzed, and a portion of the wiring where the characteristic impedance changes is set as a noise source different from other portions of the wiring. As the portion where the characteristic impedance changes is a bent portion of the wiring, the bent portion of the wiring may be detected and set as a noise source.

The form of waves transmitted by the wiring is analyzed, and a portion of the wiring where signal reflection is observed is set as a noise source different from other portions of the wiring.

The resonance of power source/GND planes is analyzed, and an space where there is a great electric field fluctuation is set as a noise source.

The noise propagation of the power source/GND planes is analyzed, and an space where a current serving as noise concentrates is set as a noise source.

A metal mechanical component is set as a noise source. For example, a metal component located within a distance set for a noise radiating component is set as a noise source.

A portion of a metal mechanical component is set as a noise source. For example, a portion of a metal component located within a distance set for a noise radiating component is set as a noise source.

In addition, a noise source attribute indicating which of the methods 01 to 03 is used to set a noise radiating component as a noise source is registered in the PCB component database 24. The noise source setting module 15 sets, as a noise source, a noise radiating component which has been extracted based on the noise source attribute.

Then, the noise intensity attribute setting module 16 sets noise intensity information for each of the extracted noise sources.

For example, when setting the noise source attribute for the noise source corresponding to the noise radiating component, the noise intensity attribute setting module 16 sets the noise source attribute based on the operation clock frequency of the noise radiating component. For example, the noise intensity attribute setting module 16 sets a plurality of levels of noise source attributes, such as high noise, intermediate noise and low noise, based on the operation clock frequency. The noise intensity attribute setting module 16 sets a higher level of noise intensity for a higher operation clock frequency. The operation clock frequency of the noise radiating component is registered in the PCB component database 24.

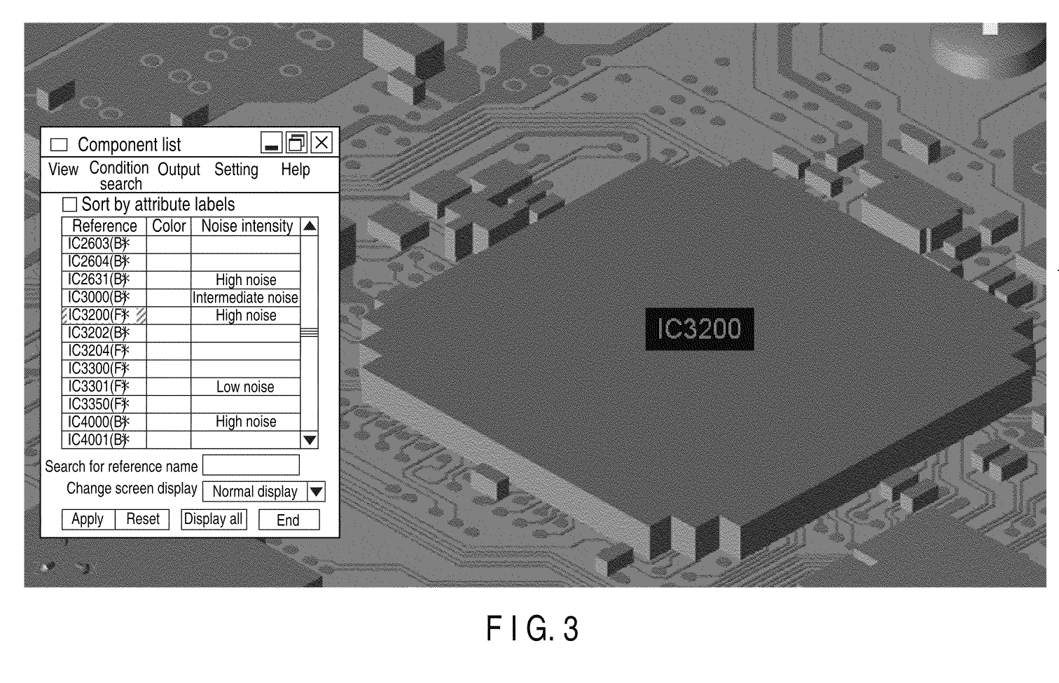

FIG. 3 shows an example of setting the noise intensity attributes for the noise sources corresponding to the noise radiating components. As shown in FIG. 3, the noise intensity attributes set for the respective noise radiating components are shown in a window. As indicated in the window in FIG. 3, a plurality of levels of noise intensity attributes are set for the respective noise radiating components, such as high noise, intermediate noise and low noise. High noise is set for IC3200 which is indicated in a magnified form in FIG. 3.

In addition, based on the distance of propagation from the noise radiating component, the noise intensity attribute setting module 16 sets, for noise of the noise propagation path, a lower level of a noise attribute (e.g., one level lower) than that for the noise source which supplies the noise. For the noise source corresponding to the portion of the wiring where the characteristic impedance changes, a higher level of intensity attribute than the intensity attributes set for the noise sources corresponding to other portions of the wiring is set. For the portion where the signal reflection is observed, a higher level of intensity attribute than the intensity attributes set for the other portions of the wiring is set.

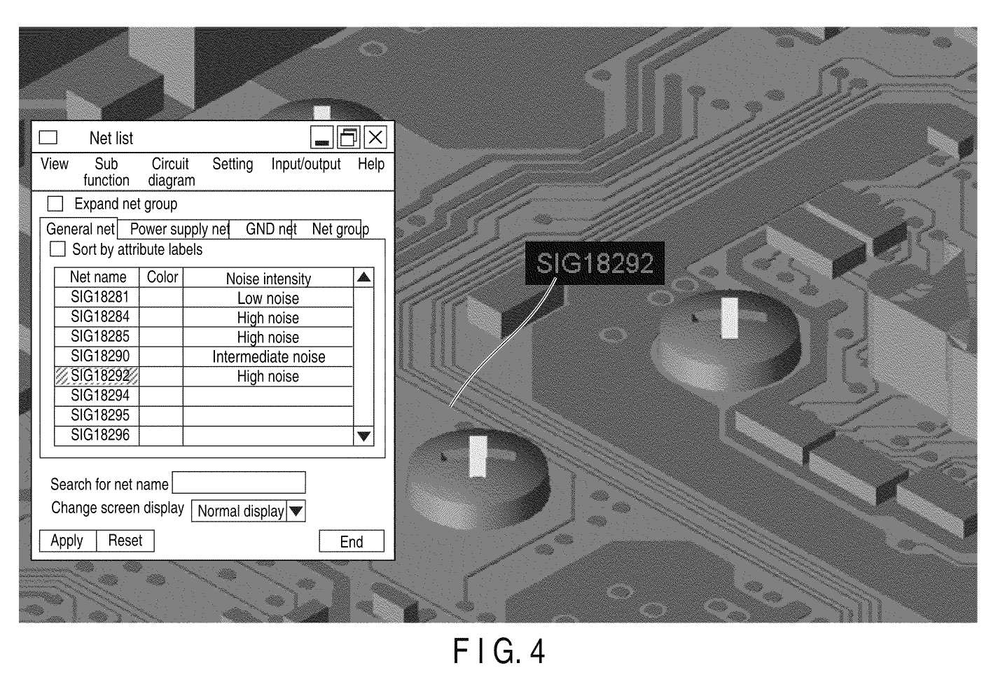

FIG. 4 shows an example of the setting noise intensity attributes for the noise sources corresponding to the wirings. In this example, noise attributes are set for the individual wirings. As shown in FIG. 4, the noise intensity attributes set for the noise sources (wirings) are indicated in a window. A plurality of levels of noise attributes are set for the respective noise sources (wirings), such as high noise, intermediate noise and low noise. Intermediate noise is set for SIG18292 which is a noise source in FIG. 4. When noise intensity attributes are set for the propagation paths, the noise intensity attributes may be obtained by a simulation.

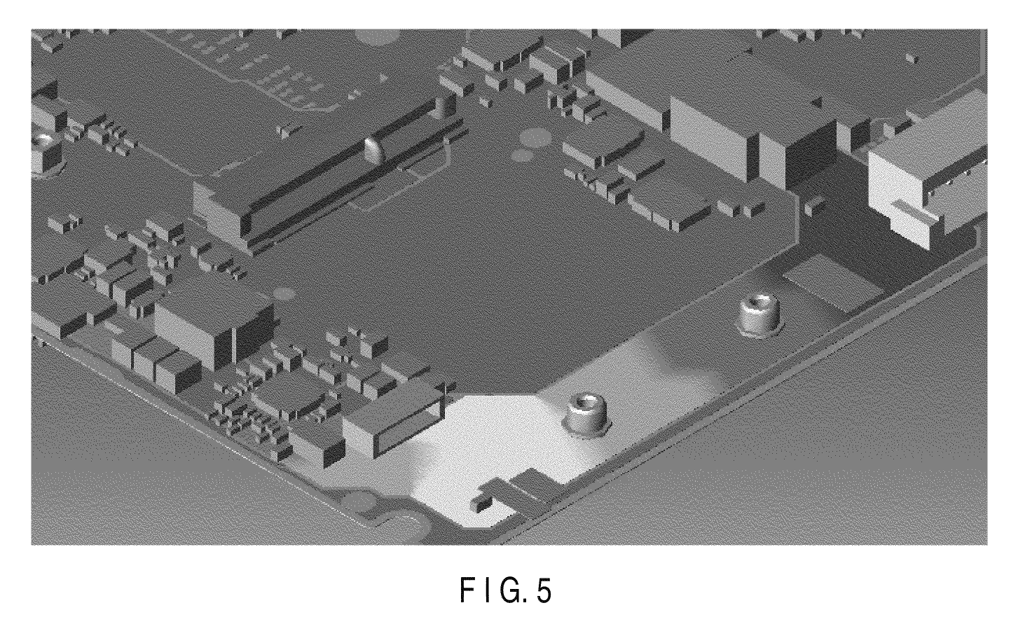

Furthermore, FIG. 5 shows an example of superposing information indicating a power source/GND resonance analysis on a figure indicating the printed circuit board. The resonance of the power source plane and the GND plane is analyzed, and the information indicating the power source/GND resonance analysis is displayed by gradations corresponding to the intensity of the fluctuation of an electric field. The noise intensity attribute setting module 16 sets one of a plurality of levels of noise attributes such as high noise, intermediate noise and low noise, based on the colors of the gradations (intensity of fluctuation of electric field).

The noise generating space setting module 17 sets noise generating spaces corresponding to the levels of the noise intensity attributes set for the respective noise sources. The noise generating space is an space around the noise source, and no cables and harnesses to be antenna elements may be disposed in this space.

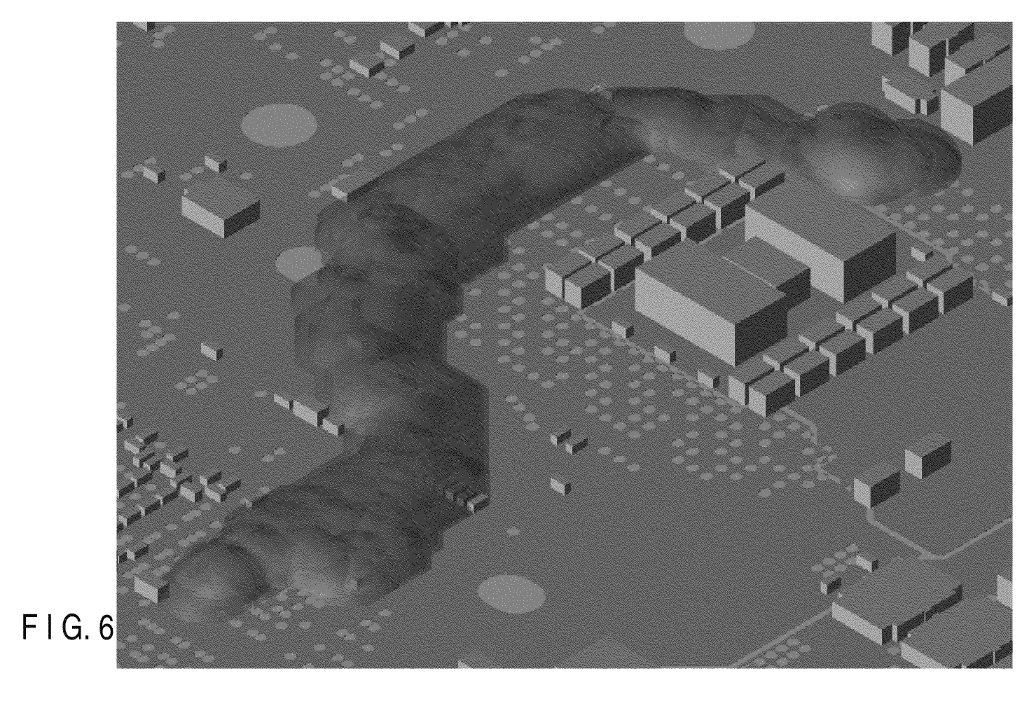

FIG. 6 shows an image in which the noise generating spaces are visualized around the noise sources (e.g., the components, wirings and spaces) on the basis of the set noise intensity attributes. The volumes of the noise generating spaces vary depending on levels such as the high noise, intermediate noise and low noise.

Then, the faulty cable/harness extraction module 18 catches the noise radiated from the noise sources based on the noise generating spaces set by the noise generating space setting module 17, the cables and harnesses extracted by the cable/harness extraction module 11, and the mechanical CAD data 21. Thus, the faulty cable/harness extraction module 18 extracts the cables and harnesses which radiate noise into space. The extracted cables and harnesses are reported to the operator. FIG. 7 shows an example of a cable which passes the noise generating space and is regarded as faulty. As shown in FIG. 7, a noise generating space 52 is set for a noise source 51. A cable 53 passes the noise generating space 52. Thus, the cable 53 radiates noise when the cable 53 is extended on this path, so that this design is regarded as faulty.

In addition, the criteria for the extraction of the cables and harnesses are simply based on whether such cables pass the noise generating space. However, a cable can also be extracted based on the volume or length of the cable passing the noise generating space or the minimum distance between the cable and the noise source.

When the faulty cable/harness extraction module 18 has extracted a cable/harness, the notification module 19 displays, on a display screen of a display, a notification urging to change the design of the extracted cable/harness.

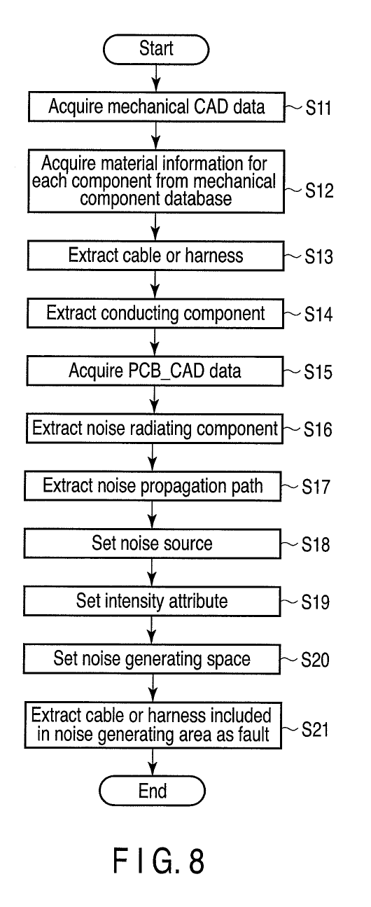

Now, a procedure for the processing to examine the placement of the cable/harness is described with reference to a flowchart in FIG. 8.

First, the cable/harness extraction module 11 acquires the mechanical CAD data 21 stored in the storage device 20 (block S11). The cable/harness extraction module 11 acquires, from the mechanical component database 22, the component material information included in the mechanical CAD data 21 (block S12). Then, the cable/harness extraction module 11 extracts a component having material information that indicates a cable or harness (block S13). Further, the conducting component extraction module 12 performs processing similar to that of the cable/harness extraction module 11, and thereby extracts a conducting component having material information that indicates a conductor (block S14).

The noise radiating component extraction module 13 acquires the PCB_CAD data 23 (block S15). The noise radiating component extraction module 13 acquires, from the PCB component database 24, the information on the components included in the PCB_CAD data 23, and extracts, as a noise radiating component, a component having an operation clock frequency greater than or equal to a set value (block S16).

The noise propagation path extraction module 14 extracts a propagation path that propagates the noise radiated from the noise radiating component extracted by the noise radiating component extraction module 13 (block S17). The noise propagation path extraction module 14 extracts, as propagation paths, a wiring directly connected to the noise radiating component and a wiring adjacent to the former wiring. The noise propagation path extraction module 14 also extracts, as a propagation path, a conducting component which is provided within a set distance from the noise radiating component and which has been extracted by the conducting component extraction module 12.

The noise source setting module 15 sets, as different noise sources, the noise radiating component which has been extracted by the noise radiating component extraction module 13 and the propagation path which has been extracted by the noise propagation path extraction module 14 (block S18).

The noise intensity attribute setting module 16 sets an intensity attribute for each noise source (block S19). The noise intensity attribute setting module 16 first sets an intensity attribute for the noise source corresponding to the noise radiating component. The noise intensity attribute setting module 16 acquires the operation clock frequency of the noise radiating component from the PCB component database 24, and sets an intensity attribute corresponding to the acquired operation clock frequency. Then, for the propagation path supplied with the noise from the noise source for which the intensity attribute has been set, the noise intensity attribute setting module 16 sets an intensity attribute lower than that for the noise source which supplies the noise.

The noise generating space setting module 17 sets a noise generating space having a volume based on the intensity attribute set for each noise source (block S20). Then, the faulty cable/harness extraction module 18 extracts a cable/harness covering the noise generating space from the cables/harnesses extracted by the cable/harness extraction module 11 (block S21). When the faulty cable/harness extraction module 18 extracts a cable/harness, the notification module 19 displays, on the display screen of the display, a notification urging to change the design of the extracted cable/harness. In addition, the design support apparatus 10 may search for a path passing a free space in the housing which does not expand through the noise generating space, and automatically change the design of the cable/harness extracted by the faulty cable/harness extraction module 18.

The intensity of the noise radiated by the noise source corresponding to the noise radiating component is set based on the operation clock frequency, and there is thus no need for processing to solve an electromagnetic field equation. This makes it possible to reduce the time required for the examination of a cable (harness) extending path that takes EMI into account.

In addition, the processing for examining the path to extend the cable or harness to be disposed in a housing according to the present embodiment is enabled by a computer program. Therefore, if this computer program is simply installed on a normal computer through a computer-readable storage medium, effects similar to the effects of the present embodiment can be easily obtained. This computer program can be executed not only on a personal computer but also on an electronic device having a processor therein.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The various modules of the systems described herein can be implemented as software applications, hardware and/or software modules, or components on one or more computers, such as servers. While the various modules are illustrated separately, they may share some or all of the same underlying logic or code. The accompanying claims and their equivalents are intended to cover such forms or modifications as would fall within the scope and spirit of the inventions.

What is claimed is:

1. A design support apparatus comprising:
a cable and harness detector configured to detect a cable and harness from mechanical design data of a housing comprising a printed circuit board, the cable and harness being connected to the printed circuit board;
a conducting component detector configured to detect a conducting component comprising a conductor from components of the housing based on the mechanical design data;
a radiating component detector configured to detect an electromagnetic wave radiating component from electronic components on the printed circuit board based on board design data for the printed circuit board, the electromagnetic wave radiating component being configured to radiate electromagnetic waves;
a propagation path detector configured to detect a propagation path configured to propagate the electromagnetic waves from the electromagnetic wave radiating component based on the board design data and the detected conducting component;
an electromagnetic wave radiation source setting module configured to set the detected electromagnetic wave radiating component and the detected propagation path as electromagnetic wave radiation sources;
an intensity setting module configured to set intensity attributes corresponding to an operation clock frequency of the electromagnetic wave radiating component for the electromagnetic wave radiation sources;
a calculator configured to calculate electromagnetic wave generating areas of the electromagnetic wave radiation sources, the electromagnetic wave generating areas comprising volumes corresponding to the intensity attributes respectively; and
a determining module configured to determine whether at least one of the cable and harness is in at least one of the electromagnetic wave generating areas.

2. The design support apparatus of claim 1, wherein the intensity setting module is configured to set a first intensity attribute to a first electromagnetic wave radiation source of the electromagnetic wave radiation sources, the first intensity attribute is selected from second intensity attributes based on the operation clock frequency, and the first electromagnetic wave radiation source comprises the electromagnetic wave radiating component, and
the intensity setting module is configured to set a third intensity attribute to a second electromagnetic wave radiation source of the electromagnetic wave radiation sources, the second electromagnetic wave radiation source comprises the propagation path, the second intensity attribute is selected from the second intensity attributes, and a level of the third intensity attribute being lower than a level of the first intensity attribute.

3. The design support apparatus of claim 2, wherein the electromagnetic wave radiation source setting module is configured to set a third electromagnetic wave radiation source to a first portion where reflection of a signal in the propagation path is observed or where the characteristic impedance of the propagation path changes, and to set a fourth electromagnetic wave radiation source to a second portion of the propagation path, and
the intensity setting module is configured to set a fourth intensity attribute to the third electromagnetic wave radiation source and to set fifth intensity attribute to the fourth electromagnetic wave radiation source, a level of the fourth intensity attribute is higher than a level of the fifth intensity attribute.

4. The design support apparatus of claim 1, wherein the electromagnetic wave radiation sources comprise the electromagnetic wave radiating component, a pin in the electromagnetic wave radiating component, and an area comprising the electromagnetic wave radiating component.

5. The design support apparatus of claim 1, wherein the electromagnetic wave radiation sources comprise an internal wiring in the printed circuit board, an external wiring on the printed circuit board, or a portion of the internal wiring.

6. A design support method comprising:
detecting a cable and harness connected to a printed circuit board from mechanical design data of a housing comprising the printed circuit board;
detecting a conducting component comprising a conductor from components of the housing based on the mechanical design data;
detecting an electromagnetic wave radiating component from electronic components on the printed circuit board based on board design data for the printed circuit board, the electromagnetic wave radiating component being configured to radiate electromagnetic waves;
detecting a propagation path configured to propagate the electromagnetic waves from the electromagnetic wave radiating component based on the board design data;
setting the electromagnetic wave radiating component and the propagation path as electromagnetic wave radiation sources;
setting intensity attributes corresponding to an operation clock frequency of the electromagnetic wave radiating component for the electromagnetic wave radiation sources;
calculating electromagnetic wave generating areas of the electromagnetic wave radiation sources, the electromagnetic wave generating areas comprising volumes corresponding to the intensity attributes respectively; and
determining whether at least one of the cable and harness is at least one of the electromagnetic wave generating areas.

7. The design support method of claim 6, further comprising:
setting a first intensity attribute to a first electromagnetic wave radiation source of the electromagnetic wave radiation sources, the first intensity attribute being selected from second intensity attributes based on the operation clock frequency, and the first electromagnetic wave radiation source comprising the electromagnetic wave radiating component; and
setting a third intensity attribute to second electromagnetic wave radiation source of the electromagnetic wave radiation sources, the second electromagnetic wave radiation source comprising the propagation path, the third intensity attribute being selected from the second intensity attributes, and a level of the third intensity attribute being lower than a level of the first intensity attribute.

8. The design support method of claim 7, further comprising:
setting a second electromagnetic wave radiation source to a first portion where reflection of a signal in the propagation path is observed or where the characteristic impedance of the propagation path changes;
setting a third electromagnetic wave radiation source to a second portion of the propagation path;
setting a fourth intensity attribute to the second electromagnetic wave radiation source; and
setting fifth intensity attribute to the third electromagnetic wave radiation source, a level of the fourth intensity attribute is higher than a level of the fifth intensity attribute.

9. A program which is stored in a computer-readable storage medium and causes a computer to examine a path to extend a cable and harness a housing, the program causes the computer to:
detect a cable and harness connected to a printed circuit board from mechanical design data of a housing comprising the printed circuit board;
detect a conducting component comprising a conductor from components of the housing based on the mechanical design data;
detect an electromagnetic wave radiating component from electronic components on the printed circuit board based on board design data for the printed circuit board, the electromagnetic wave radiating component being configured to radiate electromagnetic waves;
detect a propagation path configured to propagate the electromagnetic waves from the electromagnetic wave radiating component based on the board design data;
set the electromagnetic wave radiating component and the propagation path as electromagnetic wave radiation sources;
set intensity attributes corresponding to an operation clock frequency of the electromagnetic wave radiating component for the electromagnetic wave radiation sources;
calculate electromagnetic wave generating areas of the electromagnetic wave radiation sources, the electromagnetic wave generating areas comprising volumes corresponding to the intensity attributes respectively; and
determine whether at least one of the cable and harness is at least one of the electromagnetic wave generating areas.
